(19) United States
(12) Patent Application Publication
(10) Pub. No.: US 2023/0109163 A1
(43) Pub. Date: Apr. 6, 2023

(54) DISPLAY DEVICE

(71) Applicant: LG DISPLAY CO., LTD., SEOUL (KR)

(72) Inventors: SungHan KIM, Seoul (KR); JinMan SHIN, Bucheon-si (KR); SoonKwang HONG, Seoul (KR); DoYune KIM, Paju-si (KR)

(73) Assignee: LG DISPLAY CO., LTD., SEOUL (KR)

(21) Appl. No.: 17/940,226

(22) Filed: Sep. 8, 2022

(30) Foreign Application Priority Data
Sep. 17, 2021 (KR) 10-2021-0125063

(51) Int. Cl. H10K 59/35; H10K 59/65; H10K 50/86; H10K 50/80

(52) U.S. Cl. CPC H01L 27/3218; H01L 27/3234; H01L 51/5284; H01L 51/5293

(57) ABSTRACT

A display panel for a display device includes a display area in which a plurality of sub-pixels are disposed and a camera area which is adjacent to the display area and in which a first hole is disposed; a first plate disposed on a rear surface of the display panel and including a second hole overlapping the first hole; a front member disposed on an upper surface of the display panel; and a light blocking member covering a rear surface of the front member which is exposed through the first hole, an inner surface of the first hole, and an inner surface of the second hole.

### CROSS-REFERENCE TO RELATED APPLICATION

This application claims the priority of Korean Patent Application No. 10-2021-0125063 filed on Sep. 17, 2021, which is hereby incorporated by reference in its entirety.

### BACKGROUND

### Field of the Disclosure

The present disclosure relates to a display device, and more particularly, to a display device in which light leakage is improved and damage due to static electricity is reduced.

### Description of the Background

Display devices used in computer monitors, TVs, and mobile phones include organic light emitting displays (OLEDs) that emit light by themselves, and liquid crystal displays (LCDs) that require a separate light source.

Such display devices are being applied to more and more various fields including not only computer monitors and TVs, but also personal mobile devices, and thus, display devices having a reduced volume and weight while having a wide display area are being studied.

In addition, the display device provides optical components such as a camera, a proximity sensor and the like together in order to provide users with more various functions. However, since the optical component such as a camera needs to be exposed to the outside in order to recognize light, display devices in which a part of the display device is cut in a notch shape or a hole is formed in the display device to dispose the optical component therein are being developed.

### SUMMARY

Accordingly, the present disclosure is to provide a display device in which occurrence of noise in optical components disposed in a camera area by light emitted from a plurality of sub-pixels is reduced.

The present disclosure is also to provide a display device in which light leakage is reduced in a notch portion where an optical component is disposed.

The present disclosure is also to provide a display device in which light leakage is reduced in a through hole where an optical component is disposed.

The present disclosure is also to provide a display device in which degradation in reliability due to static electricity generated in a cover window is minimized.

The present disclosure is also to provide a display device having a reduced bezel area.

The present disclosure is also to provide a display device in which manufacturing costs are reduced by simplifying a process.

In an aspect of the present disclosure, a display device includes a display panel including a display area in which a plurality of sub-pixels are disposed and a camera area which is adjacent to the display area and in which a first hole is disposed; a first plate disposed on a rear surface of the display panel and including a second hole overlapping the first hole; a front member disposed on an upper surface of the display panel; and a light blocking member covering a rear surface of the front member which is exposed through the first hole, an inner surface of the first hole, and an inner surface of the second hole. Accordingly, according to aspects of the present disclosure, the light blocking member is formed on the inner surfaces of the first hole and the second hole, so that it is possible to block light from the plurality of sub-pixels from being transmitted into the camera area and at the same time, to discharge static electricity generated from the front member, thereby allowing for improvements in reliability of the display device.

In another aspect of the present disclosure, a display device includes a display panel including a display area in which a plurality of sub-pixels are disposed and a camera area which is adjacent to the display area and which includes a first notch portion; a first plate disposed on a rear surface of the display panel and including a second notch portion overlapping the first notch portion; a front member disposed on an upper surface of the display panel; and a light blocking member covering a rear surface of the front member and a side surface of the display panel which are exposed through the first notch portion and a side surface of the first plate which is exposed through the second notch portion. Accordingly, according to aspects of the present disclosure, the light blocking member is formed to cover a side surface of the display device which is exposed through the notch portion, so that light leakage can be improved in the notch portion and damage to the display device due to static electricity can be reduced.

According to various aspects of the present disclosure, noise due to light leakage in a camera area where an optical component is disposed can be improved.

According to various aspects of the present disclosure, damage to a display device can be reduced by discharging static electricity of a cover window.

According to various aspects of the present disclosure, a bezel area can be reduced by eliminating a conductive tape.

According to various aspects of the present disclosure, a manufacturing cost and time can be reduced by simplifying a process of attaching the conductive tape.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a plan view of a display device according to an exemplary aspect of the present disclosure;

FIG. 2 is an enlarged plan view of the display device according to an exemplary aspect of the present disclosure;

FIGS. 3A and 3B are cross-sectional views taken along line of FIG. 2;

FIG. 4 is an enlarged cross-sectional view of a display panel of the display device according to an exemplary aspect of the present disclosure;

FIG. 5 is a perspective view of a jig on which the display device is mounted when the display device is manufactured according to an exemplary aspect of the present disclosure;

FIG. 6 is a schematic cross-sectional view for explaining a method of inspecting the conductive light blocking member when the display device is manufactured according to an exemplary aspect of the present disclosure;

FIGS. 7A, 7B and 7C are views for explaining an inspection result of the conductive light blocking member when the display device is manufactured according to an exemplary aspect of the present disclosure;

FIG. 8 is a plan view of a display device according to another exemplary aspect of the present disclosure; and

FIG. 9 is a cross-sectional view of the display device according to another exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure can be partially or entirely adhered to or combined with each other and can be interlocked and operated in technically various ways, and the aspects can be carried out independently of or in association with each other.

Hereinafter, a display device according to exemplary aspects of the present disclosure will be described in detail with reference to accompanying drawings.

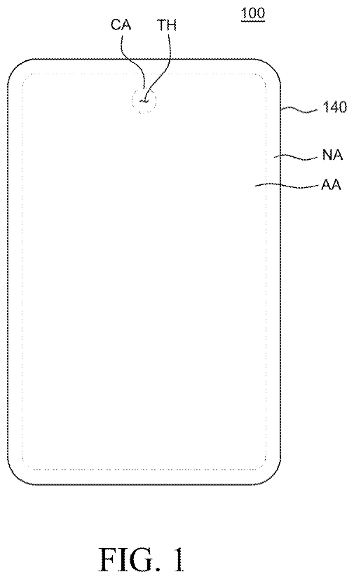

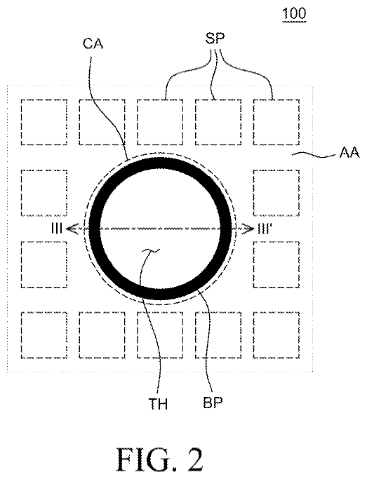

FIG. 1 is a plan view of a display device according to an exemplary aspect of the present disclosure. FIG. 2 is an enlarged plan view of the display device according to an exemplary aspect of the present disclosure. In FIGS. 1 and 2, only a display panel 140 and a conductive light blocking member 170 among various components of the display device 100 are illustrated for convenience of explanation.

The display panel 140 is a panel on which an image is implemented, and a display element for implementing an image, a circuit, lines, and components for driving the display element may be disposed on the display panel 140.

Referring to FIGS. 1 and 2, the display panel 140 includes a display area AA, a non-display area NA, and a camera area CA.

The display area AA is an area in which a plurality of sub-pixels SP are disposed to display an image. Each of the plurality of sub-pixels SP is an individual unit emitting light, and a light emitting element and a driving circuit are formed in each of the plurality of sub-pixels SP. For example, display elements for displaying an image and circuit units for driving the display elements may be disposed in the plurality of sub-pixels SP. For example, when the display device 100 is an organic light emitting display device, the display element may include an organic light emitting element, and when the display device 100 is a liquid crystal display device, the display element may include a liquid crystal element. The plurality of sub-pixels SP may include a red sub-pixel, a green sub-pixel, a blue sub-pixel, and/or a white sub-pixel, but are not limited thereto.

The non-display area NA is an area in which an image is not displayed, and is an area in which various lines, driver ICs and the like for driving the plurality of sub-pixels SP disposed in the display area AA are disposed. For example, various ICs such as a gate driver IC and a data driver IC and driving circuits, and the like may be disposed in the non-display area NA. The non-display area NA in which an image is not displayed may also be defined as a bezel area.

Meanwhile, the non-display area NA may be defined as an area surrounding the display area AA as shown in FIG. 1. However, the non-display area NA may be defined as an area extending from the display area AA or may be defined as an area in which the plurality of sub-pixels SP are not disposed, but is not limited thereto.

The camera area CA is disposed within the display area AA. The camera area CA is disposed between the plurality of sub-pixels SP in the display area AA. The camera area CA is an area in which an optical component such as a camera or a proximity sensor is disposed. The camera area CA includes a through hole TH that penetrates some components of the display device 100 to dispose the optical component. For example, a space in which the optical component is disposed may be secured by forming the through hole TH that penetrates the display panel 140.

Meanwhile, some of light emitted from the plurality of sub-pixels SP may travel toward the camera area CA disposed between the plurality of sub-pixels SP, that is, toward the through hole TH. However, when light from the plurality of sub-pixels SP travelling toward the through hole TH is transmitted to an optical component such as a camera, noise may be generated and thus, reliability of the optical component may be degraded. Accordingly, the conductive light blocking member 170 may be disposed in the through hole TH so that light emitted from the plurality of sub-pixels SP is not transmitted to an inside of the through hole TH.

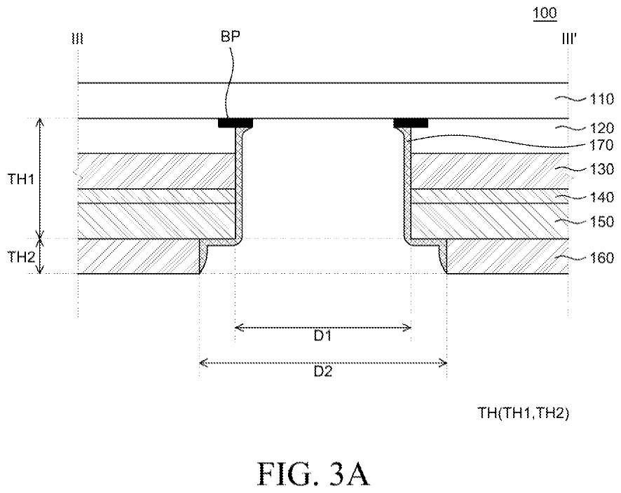

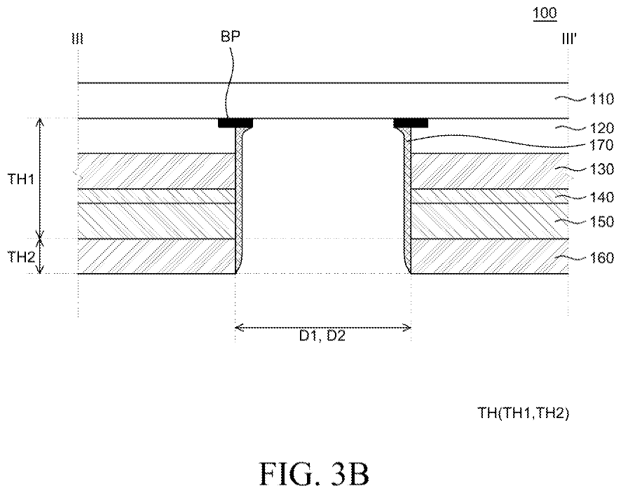

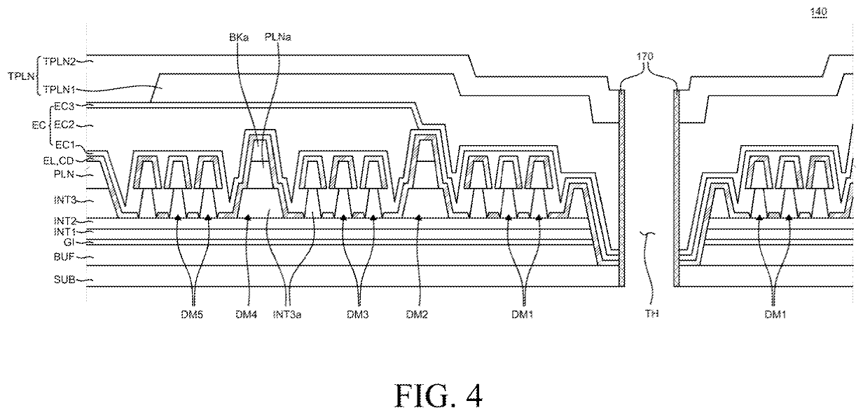

Hereinafter, the conductive light blocking member 170 and the display device 100 will be described in more detail with reference to FIGS. 3A to 4.

FIGS. 3A and 3B are cross-sectional views taken along line of FIG. 2. FIG. 3A is a cross-sectional view illustrating a case where through holes TH formed in each of a metal plate 160 and the display panel 140 have different sizes, and FIG. 3B is a cross-sectional view illustrating a case where through holes TH formed in each of the metal plate 160 and the display panel 140 have the same size. Referring to FIGS. 3A to 4, the display device 100 according to an exemplary aspect of the present disclosure includes a cover window 110, an adhesive layer 120, a polarizing plate 130, a display panel 140, a back plate 150, and the metal plate 160.

The cover window 110 is disposed on the display panel 140. The cover window 110 may protect the polarizing plate 130, the display panel 140 and the like under the cover window 110 from external impacts, moisture, heat, and the like. The cover window 110 may be formed of a material having impact resistance and light transmittance. For example, the cover window 110 may be a substrate formed of glass or may be a thin film formed of a plastic material such as polymethylmethacrylate (PMMA), polyimide (PI), or polyethylene terephthalate (PET), but is not limited thereto. In addition, the cover window 110 is an exemplary name, and may be referred to as various names such as a front member and a cover glass, but is not limited thereto.

The polarizing plate 130 is disposed between the cover window 110 and the display panel 140. The polarizing plate 130 may selectively transmit light and reduce reflection of external light incident on the display panel 140. Specifically, the display panel 140 includes various metallic materials that are applied to thin film transistors, lines, electroluminescent devices, and the like. Accordingly, the external light incident on the display panel 140 may be reflected from the metallic material, and visibility of the display device 100 may be reduced due to reflection of the external light. Accordingly, by disposing the polarizing plate 130 on one surface of the display panel 140, reflection of external light may be prevented, and outdoor visibility of the display device 100 may be improved. However, components of the display device 100 illustrated in FIGS. 3A and 3B are exemplary, and the polarizing plate 130 may be omitted depending on aspects of the display device 100.

In addition, the adhesive layer 120 may be formed between the polarizing plate 130 and the cover window 110, so that the cover window 110 may be bonded and disposed onto the polarizing plate 130. The adhesive layer 120 may be formed of a material having an adhesive property and may be formed of, for example, optical clear adhesive (OCA), pressure sensitive adhesive (PSA), or the like, but is not limited thereto.

The back plate 150 is disposed under the display panel 140. When a substrate that constitutes the display panel 140 is formed of a plastic material such as polyimide, a manufacturing process of the display device 100 is conducted in a situation in which a support substrate formed of glass is disposed under the substrate, and the support substrate may be released after forming components such as a polarizing plate and the like on the substrate. However, since components for supporting the substrate are required even after the support substrate is released, the back plate 150 for supporting the substrate may be disposed under the substrate of the display panel 140. The back plate 150 may not only support the display panel 140 and protect the display panel 140 from external moisture, heat, impacts, and the like. The back plate 150 may be, for example, a thin film formed of polyimide (PI), polyethylene terephthalate (PET), polyethylene naphthalate (PEN), or the like.

The metal plate 160 is disposed under the back plate 150. The metal plate 160 may protect and support components on the metal plate 160. Since the metal plate 160 is formed of a rigid material, it is possible to minimize occurrence of dent marks and the like due to an external impact or the like. In addition, the metal plate 160 may function as a heat dissipation member emitting heat that is generated when the display device 100 is driven. In addition, the metal plate 160 may be formed of a material having excellent electrical conductivity to discharge static electricity that is generated in the cover window 110 together with the conductive light blocking member 170 to the outside. To this end, the metal plate 160 may be formed of a material having excellent thermal conductivity and electrical conductivity, for example, copper (Cu), graphite and the like, but is not limited thereto.

Meanwhile, in the present specification, components disposed under the display panel 140 are referred to as the back plate 150 and the metal plate 160, but the back plate 150 and the metal plate 160 may be referred to as other names, for example, the metal plate 160 may be referred to as a first plate and the back plate 150 may be referred to as a second plate, but they are not limited thereto.

The through holes TH are formed in remaining components of the display device 100 except for the cover window 110. The through holes TH may be formed through the adhesive layer 120, the polarizing plate 130, the display panel 140, the back plate 150, and the metal plate 160. The through hole TH is an empty space in which an optical component such as a camera is disposed in the display area AA. The optical component may be disposed in the through hole TH and recognize an external environment outside the cover window 110. The optical component may be operated by recognizing external light that is transmitted to the optical component through the cover window 110. In this case, since the through hole TH is not formed in the cover window 110, it is possible to prevent foreign substances from penetrating into the through hole TH.

Meanwhile, a size of the through hole TH of the metal plate 160 may be configured differently according to an order of an attachment process of the metal plate 160 and a formation process of the through hole TH. Hereinafter, for convenience of explanation, through holes TH that are continuously formed in the adhesive layer 120, the polarizing plate 130, the display panel 140, and the back plate 150, that is, a through hole TH that is disposed along the adhesive layer 120, the polarizing plate 130, the display panel 140, and the back plate 150 is referred to as a first through hole TH1, and a through hole TH that is formed in the metal plate 160 is referred to as a second through hole TH2. However, the first through hole TH1 and the second through hole TH2 are exemplary, and the first through hole TH1 may be referred to as a first hole and the second through hole TH2 may be referred to as a second hole, but they are not limited thereto.

For example, referring to FIG. 3A, after a first through hole TH1 having a first diameter D1 is formed in the adhesive layer 120, the polarizing plate 130, the display panel 140, and the back plate 150 at a time, the metal plate 160 that is provided with a second through hole TH2 having a second diameter D2 may be attached to a rear surface of the back plate 150. In this case, the first diameter D1 of the first through hole TH1 may be smaller than the second diameter D2 of the second through hole TH2. If the second through hole TH2 is smaller than the first through hole TH1, it may be difficult to align the second through hole TH2 and the first through hole TH1 when the metal plate 160 is attached, and it may be difficult to form the conductive light blocking member 170, which will be described later, within the first through hole TH1. Accordingly, when the first through hole TH1 is formed before the metal plate 160 is attached, the display device 100 may be manufactured by attaching the adhesive layer 120, the polarizing plate 130, the display panel 140, and the back plate 15, in which the first through hole TH1 is formed, and the metal plate 160 in which the second through hole TH2 having a larger diameter than the first through hole TH1 is formed.

For another example, referring to FIG. 3B, the through holes TH may be formed after attaching the adhesive layer 120, the polarizing plate 130, the display panel 140, the back plate 150, and the metal plate 160. In this case, the diameter D1 of the first through hole TH1 that is formed in the adhesive layer 120, the polarizing plate 130, the display panel 140, and the back plate 150 may be identical to the diameter D2 of the second through hole TH2 that is formed in the metal plate 160. However, sizes of the through holes TH formed in the adhesive layer 120, the polarizing plate 130, the display panel 140, the back plate 150, and the metal plate 160 may be variously configured, and are not limited thereto.

The light blocking member 170 is disposed within the through hole TH. The light blocking member 170 may be formed of a conductive material and may be referred to as the conductive light blocking member 170. The conductive light blocking member 170 is a component to block light from the display panel 140 from being introduced into the through hole TH and discharge static electricity generated from the cover window 110. The conductive light blocking member 170 may cover a portion of the cover window 110, a side (or lateral) surface of the adhesive layer 120, a side (or lateral) surface of the polarizing plate 130, a side (or lateral) surface of the display panel 140, a side (or lateral) surface of the back plate 150, and a side (or lateral) surface of the metal plate 160 that are exposed through the through hole TH. The conductive light blocking member 170 may be disposed to cover an inner circumferential surface of the through hole TH and a portion of a rear surface of the cover window 110 corresponding to a circumference of the through hole TH. One end of the conductive light blocking member 170 may be disposed on the cover window 110, and the other end of the conductive light blocking member 170 may be in contact with the metal plate 160. The conductive light blocking member 170 may overlap a portion of the metal plate 160.

For example, referring to FIG. 3A, the conductive light blocking member 170 may cover the rear surface of the cover window 110, a boundary portion between the rear surface of the cover window 110 and the side surface of the adhesive layer 120, the side surface of the adhesive layer 120, the side surface of the polarizing plate 130, the side surface of the display panel 140, and the side surface of the back plate 150. In addition, the conductive light blocking member 170 may cover the rear surface of the back plate 150 that is exposed through the second through hole TH2, a boundary portion between the rear surface of the back plate 150 and the side surface of the metal plate 160, and the side surface of the metal plate 160. Accordingly, when the second through hole TH2 of the metal plate 160 is greater than the first through hole TH1 of the adhesive layer 120, the polarizing plate 130, the display panel 140, and the back plate 150, the conductive light blocking member 170 may cover up to a portion of the back plate 150 that is exposed through the second through hole TH2.

For another example, referring to FIG. 3B, the conductive light blocking member 170 may cover the rear surface of the cover window 110, a boundary portion between the rear surface of the cover window 110 and the side surface of the adhesive layer 120, the side surface of the adhesive layer 120, the side surface of the polarizing plate 130, the side surface of the display panel 140, the side surface of the back plate 150, and the side surface of the metal plate 160.

Meanwhile, referring to FIGS. 3A and 3B, the conductive light blocking member 170 covers only the side (or lateral) surface of the metal plate 160 and does not cover a rear surface of the metal plate 160. That is, an end portion of the conductive light blocking member 170 may not be disposed outside the through hole TH, but may be disposed only within the through hole TH. If the conductive light blocking member 170 is disposed to cover up to the rear surface of the metal plate 160, other components on the metal plate 160 and the conductive light blocking member 170 may interfere with each other or a short circuit may occur therebetween. For example, a circuit board for driving an optical component may be disposed on the metal plate 160, and the circuit board and the conductive light blocking member 170 on the rear surface of the metal plate 160 may interfere with each other, causing a short circuit. In addition, when a structure such as a frame or the like is attached to the rear surface of the metal plate 160, interference with the conductive light blocking member 170 may occur. Accordingly, the conductive light blocking member 170 may be disposed only within the through hole TH.

The conductive light blocking member 170 may be formed of an opaque and electrically conductive material to discharge static electricity while preventing light leakage. The conductive light blocking member 170 may be formed of a conductive ink or conductive paste. For example, the conductive light blocking member 170 may be formed of a conductive ink in which conductive particles such as carbon black or a conductive polymer such as PEDOT:PSS (poly(3,4-ethylenedioxythiophene)) are mixed, or a conductive paste formed of a material such as silver or the like. Also, the conductive light blocking member 170 may have a resistance of 0 to 10⁶ Ω to discharge static electricity. However, the conductive light blocking member 170 may be formed of various materials other than materials described above, but is not limited thereto.

Meanwhile, the conductive light blocking member 170 may be formed using a process such as pneumatic spray coating or electrostatic spray coating. For example, pneumatic spray coating is a method in which a material inside a syringe is pushed and sprayed by using air pressure, and electrostatic spray coating is a method in which after an electric charge is given by applying a voltage to a material, and the charged material is sprayed using a spray nozzle. If the conductive light blocking member 170 is formed by pneumatic spray coating or electrostatic spray coating, a viscosity of the conductive light blocking member 170 may be about 10,000 cPs or less. However, besides this, the conductive light blocking member 170 may be formed in various other ways, but is not limited thereto.

A print pattern BP is disposed between the cover window 110 and the conductive light blocking member 170. The print pattern BP may be disposed along the circumference of the through hole TH on the rear surface of the cover window 110. At least one of the first through hole TH1 and the second through hole TH2 may overlap the print pattern BP.

In this case, the print pattern BP may discharge static electricity that is generated in the cover window 110 to the metal plate 160 together with the conductive light blocking member 170. The print pattern BP may be formed of an insulating material or a conductive material such as the conductive light blocking member 170, and may be formed of, for example, black ink, ink containing a conductive material, silver paste, or the like. In this case, even if the print pattern BP is formed of an insulating material and the conductive light blocking member 170 is indirectly connected to the cover window 110 through the print pattern BP, static electricity that is generated in the cover window 110 may be easily discharged. Meanwhile, in the present specification, a component formed on the rear surface of the cover window 110 is referred to as the print pattern BP, but the print pattern BP may also be referred to as a pattern, and is not limited thereto.

Meanwhile, in the display panel 140 among components in direct contact with the conductive light blocking member 170, a plurality of lines to which various signals are supplied, and the like are disposed on the substrate. Even if the conductive light blocking member 170 is formed on an inner surface of the through hole TH to which an inside of the display panel 140 is directly exposed, without a separate insulating layer, the display panel 140 can be easily driven.

Hereinafter, a detailed structure of the display panel 140 in the camera area CA will be described with reference to FIG. 4.

FIG. 4 is an enlarged cross-sectional view of a display panel of the display device according to an exemplary aspect of the present disclosure.

Referring to FIG. 4, the display panel 140 includes a substrate SUB, a buffer layer BUF, a gate insulating layer GI, a first interlayer insulating layer INT 1, a second interlayer insulating layer INT2, a third interlayer insulating layer INT3, a planarization layer PLN, an emission layer EL and a cathode CD of the light emitting element, an encapsulation unit EC, an additional planarization layer TPLN, and a plurality of dams DM.

The substrate SUB is a support member for supporting other components of the display device 100, and may be formed of an insulating material. For example, the substrate SUB may be formed of glass or resin or the like. In addition, the substrate SUB may be formed to include a polymer or plastic such as polyimide (PI), or may be formed of a material having flexibility.

As a plurality of lines, thin film transistors, light emitting elements, and the like are disposed in the plurality of sub-pixels SP of the display area AA on the substrate SUB, a plurality of insulating layers may be formed on the substrate SUB. Hereinafter, descriptions are made assuming that the buffer layer BUF, the gate insulating layer GI, the first interlayer insulating layer INTI, the second interlayer insulating layer INT2, the third interlayer insulating layer INT3, the planarization layer PLN, and a bank are disposed on the substrate SUB, but the components of the display device 100 are exemplary and are not limited thereto.

The buffer layer BUF is disposed on the substrate SUB. The buffer layer BUF may prevent moisture or impurities from penetrating through the substrate SUB. The buffer layer BUF may be formed of, for example, a single layer or multilayers of silicon oxide (SiOx) or silicon nitride (SiNx), but is not limited thereto.

Thin film transistors including an active layer, a gate electrode, a source electrode, and a drain electrode may be disposed in the plurality of sub-pixels SP on the buffer layer BUF. The gate insulating layer GI may be disposed on the buffer layer BUF to insulate the active layer and the gate electrode. The gate insulating layer GI is an insulating layer for insulating the active layer and the gate electrode, and may be formed of a single layer or multilayers of silicon oxide (SiOx) or silicon nitride (SiNx), but is not limited thereto.

The first interlayer insulating layer INT1, the second interlayer insulating layer INT2, and the third interlayer insulating layer INT3 may be sequentially disposed on the gate insulating layer GI. The first interlayer insulating layer INTI, the second interlayer insulating layer INT2, and the third interlayer insulating layer INT3 may be disposed between the respective components of the thin film transistor and the plurality of lines and insulate them. For example, the first interlayer insulating layer INTI, the second interlayer insulating layer INT2, and the third interlayer insulating layer INT3 may be disposed between the gate electrode, the source electrode and the drain electrode of the thin film transistor, and the data line. Each of the first interlayer insulating layer INTI, the second interlayer insulating layer INT2, and the third interlayer insulating layer INT3 may be composed of a single layer or multilayers of silicon oxide (SiOx) or silicon nitride (SiNx) which is an inorganic material or may be composed of a single layer or multilayers of polyimide or photo acryl, which is an organic material, but is not limited thereto.

The planarization layer PLN is disposed on the third interlayer insulating layer INT3. The planarization layer PLN is an insulating layer that planarizes an upper portion of the substrate SUB. The planarization layer PLN may be formed of an organic material, for example, a single layer or multilayers of polyimide or photo acryl, but is not limited thereto.

Although not shown in the drawings, the light emitting element including an anode, an emission layer EL, and a cathode CD may be disposed on the planarization layer PLN in the display area AA.

The anode may be disposed in each of the plurality of sub-pixels SP on the planarization layer PLN. The anode may be connected to a plurality of the thin film transistors and receive a voltage applied thereto. The anode may be formed of a transparent conductive material such as indium tin oxide (ITO) or indium zinc oxide (IZO), but is not limited thereto. In addition, when the display device 100 is configured as a top emission type, a reflective layer may be further disposed on the anode to reflect light emitted from the light emitting element upwardly of the substrate SUB. For example, the reflective layer may include a material having excellent reflectivity such as aluminum (Al) or silver (Ag), but is not limited thereto.

The bank may be disposed between the plurality of sub-pixels SP on the anode. The bank is an insulating layer that is disposed to separate the plurality of sub-pixels SP, and may cover an edge of the anode of each of the plurality of sub-pixels SP. The bank may be formed of an organic material, and the bank 132 may be formed of a polyimide, acryl, or benzocyclobutene (BCB)-based resin, but is not limited thereto.

The emission layer EL may be disposed on the anode and the bank. The emission layer EL may be an organic layer for emitting light of a specific color. In addition, the emission layer EL may further include various layers such as a hole transport layer, a hole injection layer, a hole blocking layer, an electron injection layer, an electron blocking layer, and an electron transport layer. As shown in FIG. 4, the emission layer EL may be formed over an entire surface of the substrate SUB or may be formed separately in each of the plurality of sub-pixels SP.

The cathode CD is disposed on the emission layer EL. The cathode CD may be formed as a single layer over the entire surface of the substrate SUB. The cathode CD may be commonly formed in the plurality of sub-pixels SP. The cathode CD may be formed of, for example, a transparent conductive material such as indium tin oxide (ITO), indium zinc oxide (IZO) or the like, a metal alloy such as MgAg, or an alloy of ytterbium (Yb) or the like, but is not limited thereto.

The encapsulation unit EC is disposed on the light emitting element. The encapsulation unit EC is a sealing layer for protecting the light emitting element from moisture, oxygen and the like penetrating from an outside of the display device 100. The encapsulation unit EC includes a first inorganic layer EC1, an organic layer EC2, and a second inorganic layer EC3.

The first inorganic layer EC1 may be disposed on the cathode CD and block moisture or oxygen from penetrating into the display device 100. The first inorganic layer EC1 may be formed of an inorganic material such as silicon nitride (SiNx), silicon oxynitride (SiNxOy), or aluminum oxide (AlyOz), but is not limited thereto.

The organic layer EC2 may be disposed on the first inorganic layer EC1 and planarize the upper portion of the substrate SUB including the first inorganic layer EC1. The organic layer EC2 may cover foreign substances or particles that may be generated during a manufacturing process. The organic layer EC2 may be formed of an organic material, for example, silicon oxycarbon (SiOxCz), acryl or epoxy-based resin, but is not limited thereto.

The second inorganic layer EC3 may be disposed on the organic layer EC2 and prevent penetration of moisture or oxygen like the first inorganic layer EC1. The second inorganic layer EC3 and the first inorganic layer EC1 may be formed to seal the organic layer EC2. For example, the first inorganic layer EC1 and the second inorganic layer EC3 may extend to an outside of the organic layer EC2, contact each other and seal the organic layer EC2. The second inorganic layer EC3 may be formed of an inorganic material such as silicon nitride (SiNx), silicon oxynitride (SiNxOy), or aluminum oxide (AlyOz), but is not limited thereto.

Meanwhile, a plurality of dams DM are disposed around the through hole TH. At least some of the plurality of dams DM may be formed in a shape of a closed curve surrounding the through hole TH. The plurality of dams DM may prevent the organic layer EC2 of the encapsulation unit EC from overflowing toward the through hole TH. The plurality of dams DM may block external moisture from penetrating into the display area AA.

The plurality of dams DM include first dams DM1, a second dam DM2, third dams DM3, a fourth dam DM4, and fifth dams DM5. The first dams DM1 are disposed closest to the through hole TH. The fifth dams DM5 are disposed closest to the display area AA. The third dams DM3 are disposed between the first dams DM1 and the fifth dams DM5. In addition, the second dam DM2 is disposed between the first dams DM1 and the third dams DM3, and the fourth dam DM4 is disposed between the third dams DM3 and the fifth dams DM5.

Each of the first dams DM1, the third dams DM3, and the fifth dams DM5 may be composed of a plurality of dams DM that are spaced apart from each other by a predetermined distance. In FIG. 4, three first dams DM1, three third dams DM3, and three fifth dams DM5 are illustrated as being arranged, but the present disclosure is not limited thereto.

The plurality of dams DM may be formed by patterning some of a plurality of the insulating layers disposed on the substrate SUB. For example, the first dam DM1, the third dam DM3, and the fifth dam DM5 may include a first layer INT3a that is formed by patterning the third interlayer insulating layer INT3 and a second layer PLNa that is formed by patterning the planarization layer PLN.

The first dam DM1, the third dam DM3, and the fifth dam DM5 may prevent moisture from penetrating into the display area AA through the emission layer EL. For example, the emission layer EL, which is vulnerable to moisture penetration, may be formed on the entire surface of the substrate SUB and partially exposed through the through hole TH. The first dam DM1, the third dam DM3, and the fifth dam DM5 may disconnect the emission layer EL to thereby reduce penetration of moisture through the emission layer EL.

In this case, in order to easily disconnect the emission layer EL, each of the first dam DM1, the third dam DM3, and the fifth dam DM5 may be configured such that a width of the first layer INT3a under the second layer PLNa is smaller than that of the second layer PLNa. As the width of the first layer INT3a formed by patterning the third interlayer insulating layer INT3 is configured to be smaller than the width of the second layer PLNa formed by patterning the planarization layer PLN, the emission layer EL may be disconnected in the first dam DM1, the third dam DM3, and the fifth dam DM5. In this case, similarly to the emission layer EL, the cathode CD formed on the entire surface of the substrate SUB may be discontinued in the first dam DM1, the third dam DM3 and the fifth dam DM5.

Meanwhile, the encapsulation unit EC may cover the emission layer EL and the cathode CD that are discontinued in the dams DM. For example, the first inorganic layer EC1 and the second inorganic layer EC3 may cover both the emission layer EL and the cathode CD that are discontinued. Accordingly, even if moisture penetrates through the emission layer EL that is exposed through the through hole TH, it is possible to prevent moisture from moving to the display area AA by the first dam DM1, the third dam DM3, the fifth dam DMS, and the encapsulation unit EC.

The second dam DM2 and the fourth dam DM4 may be formed in a shape of a closed curve surrounding the through hole TH. The second dam DM2 and the fourth dam DM4 may include a first layer INT3a that is formed by patterning the third interlayer insulating layer INT3, a second layer PLNa that is formed by patterning the planarization layer PLN, and a third layer BKa that is formed by patterning the bank.

The second dam DM2 and the fourth dam DM4 may prevent the organic layer EC2 of the encapsulation unit EC from overflowing into the through hole TH. The organic layer EC2 may be formed up to an inside of the second dam DM2. However, although it is illustrated in FIG. 4 that the organic layer EC2 is formed up to the inside of the second dam DM2, the organic layer EC2 may be formed up to an inside of the fourth dam DM4, but is not limited thereto.

In addition, the additional planarization layer TPLN is disposed on the encapsulation unit EC. The additional planarization layer TPLN includes a first additional planarization layer TPLN1 and a second additional planarization layer TPLN2. For example, when a touch unit is disposed on the encapsulation unit EC, the first additional planarization layer TPLN1 and the second additional planarization layer TPLN2 may be further disposed to form touch electrodes in a flat manner and insulate the touch electrodes from each other. The first additional planarization layer TPLN1 may cover an area in which the plurality of dams DM are formed from the through hole TH, and the second additional planarization layer TPLN2 may cover the entire surface of the substrate SUB. However, the first additional planarization layer TPLN1 and the second additional planarization layer TPLN2 may be omitted according to a design of the touch unit, but is not limited thereto.

However, a configuration and arrangement of the display panel 140 illustrated in FIG. 4 are exemplary and are not limited thereto.

Meanwhile, the inside of the display panel 140 is exposed through the through hole TH. For example, the substrate SUB, the emission layer EL, the cathode CD, the encapsulation unit EC, the first additional planarization layer TPLN1, and the second additional planarization layer TPLN2 of the display panel 140 may be exposed through the through hole TH. The substrate SUB, the encapsulation unit EC, the first additional planarization layer TPLN1, and the second additional planarization layer TPLN2 of which side surfaces are exposed through the through hole TH, are formed of an insulating material, so they do not affect the inside of the display panel 140 even if they come into contact with the conductive light blocking member 170. On the other hand, since the cathode CD and the emission layer EL of which the side surfaces are exposed through the through hole TH are not formed of an insulating material, but are discontinued with the cathode CD and the emission layer EL of the display area AA by the plurality of dams DM. Therefore, the cathode CD and the emission layer EL of which the side surfaces are exposed through the through hole TH do not affect the plurality of sub-pixels SP of the display area AA even if the conductive light blocking member 170 is in contact with the side surfaces of the cathode CD and the emission layer EL. Accordingly, even if the conductive light blocking member 170 is directly formed on the inner surface of the through hole TH without forming a separate insulating layer, driving inside the display panel 140 may not be affected.

In the display device 100 according to an exemplary aspect of the present disclosure, it is possible to prevent light from the display panel 140 from being transmitted to an optical component by forming the conductive light blocking member 170 in the through hole TH where the optical component is disposed. Specifically, the conductive light blocking member 170 may be disposed to cover the inner surface of the through hole TH and block light emitted from the plurality of sub-pixels SP from being directed into the through hole TH. If the light from the plurality of sub-pixels SP is transmitted to an inside of the through hole TH, recognition of external light of the optical component may be interfered and reliability of the optical component may be degraded. That is, light from the plurality of sub-pixels SP may act as noise. Accordingly, in the display device 100 according to the exemplary aspect of the present disclosure, the conductive light blocking member 170 may be disposed inside the through hole TH to thereby prevent light leakage and improve the reliability of the optical component.

In the display device 100 according to an exemplary aspect of the present disclosure, static electricity generated in the cover window 110 may be discharged using the conductive light blocking member 170. The cover window 110 is a component that is exposed to the outside of the display device 100, and static electricity may be easily generated therein by friction with the outside. However, when static electricity generated in the cover window 110 is introduced into the display panel 140, components inside the display panel 140 may be damaged, which may lead to a defect in the display device 100. In this case, the conductive light blocking member 170 may be formed of a material having electrical conductivity, and may discharge static electricity generated in the cover window 110 to the metal plate 160. The metal plate 160 is electrically grounded and configured to discharge static electricity. The conductive light blocking member 170 may be connected between the metal plate 160 and the cover window 110 and form a path through which static electricity generated from the cover window 110 is discharged. Accordingly, in the display device 100 according to an exemplary aspect of the present disclosure, the conductive light blocking member 170 connecting the cover window 110 and the metal plate 160 is disposed, so that static electricity of the cover window 110 may be discharged and the introduction of static electricity into the display panel 140 may be minimized.

In the display device 100 according to an exemplary aspect of the present disclosure, a process may be simplified and manufacturing costs may be reduced by using the conductive light blocking member 170 having an integrated function of preventing light leakage and discharging static electricity. Conventionally, a process of forming a light blocking ink to prevent light leakage in the through hole and a process of attaching a conductive tape to the inside of the display device for discharging static electricity were separately performed. On the other hand, in the display device 100 according to an exemplary aspect of the present disclosure, the light blocking member 170 that prevents light leakage in the through hole TH has conductivity and thus may also perform an electrostatic discharge function. Accordingly, the process of attaching the conductive tape can be eliminated, and the manufacturing cost can be reduced. Thus, in the display device 100 according to an exemplary aspect of the present disclosure, some processes may be eliminated and manufacturing costs may be reduced by using the conductive light blocking member 170.

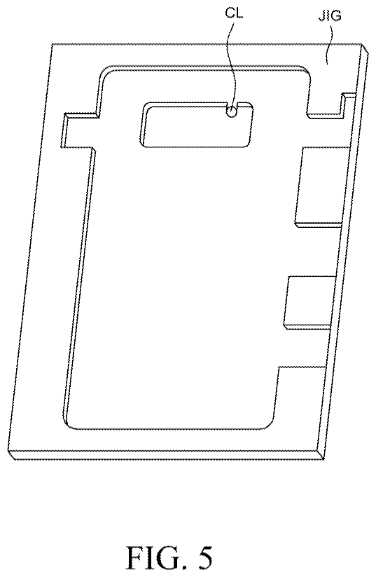

Meanwhile, when the conductive light blocking member 170 is formed, in a case where there occurs a defect in which the conductive light blocking member 170 is not applied to a partial area, light leakage may occur and noise of the optical component may occur. Accordingly, in the display device 100 according to an exemplary aspect of the present disclosure, whether or not the conductive light blocking member 170 is defective may be inspected during image quality inspection of the display device 100. Hereinafter, a method of inspecting the conductive light blocking member 170 in the display device 100 according to an exemplary aspect will be described with reference to FIGS. 5 to 7.

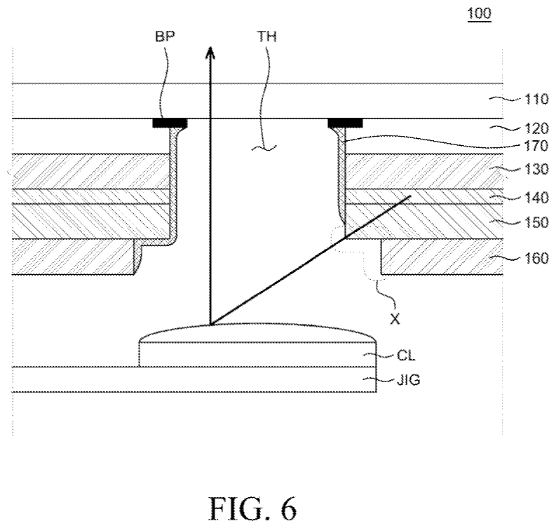

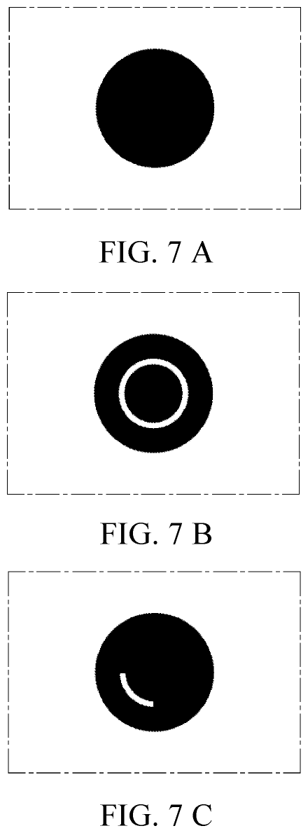

FIG. 5 is a perspective view of a jig on which the display device is mounted when the display device is manufactured according to an exemplary aspect of the present disclosure. FIG. 6 is a schematic cross-sectional view for explaining a method of inspecting the conductive light blocking member when the display device is manufactured according to an exemplary aspect of the present disclosure. FIG. 7 is a view for explaining an inspection result of the conductive light blocking member when the display device is manufactured according to an exemplary aspect of the present disclosure.

Referring to FIG. 5, a jig is a component on which the display device 100 is mounted when the image quality of the display device 100 is inspected. Defects such as dark spots or bright spots may be inspected by driving the display device 100 in a state in which the display device 100 is placed on the jig. For example, an image defect, for example, a defect such as a dark spot or a bright spot may be detected by inspecting the display device 100 using a vision method in a state in which the display device 100 is driven.

Referring to FIG. 6 together, the conductive light blocking member 170 may be inspected together when the image quality is inspected by forming a convex lens CL in a portion corresponding to the through hole TH in the jig. Specifically, light emitted from the plurality of sub-pixels SP by driving the display device 100 may be displayed on the entire surface of the display device 100 during the image quality inspection. The light emitted from the plurality of sub-pixels SP may travel not only toward a front surface of the display device 100, but also travel toward a side surface or a rear surface or the like of the display device 100, some of which may travel toward the through hole TH inside the display device 100. If there is an unapplied area X to which the conductive light blocking member 170 is not applied, light from the plurality of sub-pixels SP may travel into the through hole TH through the unapplied area X. In addition, some of the light traveling into the through hole TH may be reflected by the convex lens CL and directed toward the front surface of the display device 100, and may be sensed by a camera that images the display device 100.

For example, referring to FIG. 7A, when the conductive light blocking member 170 is applied to an entirety of the through hole TH and there is no unapplied area X, the light emitted from the plurality of sub-pixels SP may not travel into the through hole TH. Accordingly, when the conductive light blocking member 170 is normally formed, light cannot be sensed in a through hole TH portion during the image quality inspection of the display device 100, and it can be seen that a portion corresponding to the through hole TH is displayed only in black.

For example, referring to FIGS. 7B and 7C, as shown in FIG. 6, when the conductive light blocking member 170 is not applied to a portion of the through hole TH, thereby resulting in the occurrence of the unapplied area X, the light emitted from the plurality of sub-pixels SP may travel into the through hole TH through the unapplied area X. In addition, since the light traveling into the through hole TH is reflected by the convex lens CL that is disposed to correspond to the through hole TH, light may be sensed in the through hole TH portion during the image quality inspection. For example, when the unapplied area X occurs in the entire through hole TH, as shown in FIG. 7B, a light leakage area that is entirely formed can be seen. When the unapplied area X occurs only in a part of the through hole TH, as shown in FIG. 7C, a light leakage area can be seen only in the part. Therefore, when the conductive light blocking member 170 is abnormally formed, light can be sensed in the through hole TH portion during the image quality inspection of the display device 100, and it can be seen that a part of the portion corresponding to the through hole TH is displayed in white.

Accordingly, in the display device 100 according to an exemplary aspect of the present disclosure, the convex lens CL that is disposed to correspond to the through hole TH is formed in the jig, so that image quality inspection and defect inspection of the conductive light blocking member 170 may be performed at the same time, and a process can be simplified. Conventionally, the inspection of the conductive light blocking member and the image quality inspection were performed separately. For example, in the image quality inspection, the image quality inspection is performed after the front surface of the display device is positioned upwardly. However, in the inspection of the conductive light blocking member, after the rear surface of the display device is positioned upwardly on a separate device, whether light leakage occurred was inspected by driving the display device. Unlike this, in the display device 100 according to an exemplary aspect of the present disclosure, the convex lens CL is formed on the jig on which the display device 100 is mounted during the image quality inspection, and light reflected from the convex lens CL is sensed when light leakage occurs, so that a defect in which the conductive light blocking member 170 is not applied can be detected. Accordingly, in the display device 100 according to an exemplary aspect of the present disclosure, when the image quality is inspected, the defect in which the conductive light blocking member 170 is not applied can be detected together, so that a process can be simplified and a manufacturing cost can be reduced.

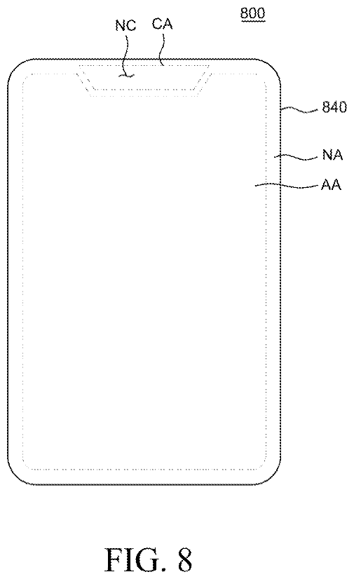

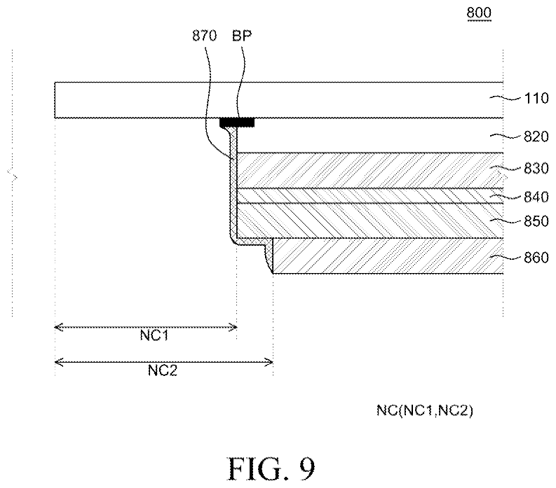

FIG. 8 is a plan view of a display device according to another exemplary aspect of the present disclosure. FIG. 9 is a cross-sectional view of the display device according to another exemplary aspect of the present disclosure. A display device 800 of FIGS. 8 and 9 differs from the display device 100 of FIGS. 1 to 4 only in terms of a camera area CA, but other configurations thereof are substantially the same, so a redundant description thereof will be omitted.

Referring to FIG. 8, a display panel 840 includes a display area AA, a non-display area NA, and the camera area CA. The camera area CA may be disposed outside the display area AA. In addition, the camera area CA includes a notch portion NC that is formed by partially removing a central portion of an upper end of the display area AA. Accordingly, upper end portions of the display area AA may be disposed to be spaced apart from each other with the camera area CA provided with the notch portion NC, therebetween.

Referring to FIG. 9, the notch portion NC is formed together in remaining components except for the cover window 110. The notch portion NC may be formed by removing an adhesive layer 820, a polarizing plate 830, the display panel 840, a back plate 850, and a metal plate 860 that corresponds to the camera area CA. The notch portion NC may be a groove from which the adhesive layer 820, the polarizing plate 830, the display panel 840, the back plate 850, and the metal plate 860 are removed. In addition, an optical component may be disposed in the notch portion NC, which is an empty space formed by removing the adhesive layer 820, the polarizing plate 830, the display panel 840, the back plate 850, and the metal plate 860.

In addition, in order to prevent light from the plurality of sub-pixels SP from being introduced toward the notch portion NC, a conductive light blocking member 870 is formed to cover the notch portion NC. The conductive light blocking member 870 may be disposed to cover a side (or lateral) surface of the adhesive layer 820, a side (or lateral) surface of the polarizing plate 830, a side (or lateral) surface of the display panel 840, a side (or lateral) surface of the back plate 850, and a side (or lateral) surface of the metal plate 860 that are exposed from the notch portion NC.

Hereinafter, for convenience of explanation, the notch portion NC formed in the adhesive layer 820, the polarizing plate 830, the display panel 840, and the back plate 850 will be referred to as a first notch portion NC1, and the notch portion NC formed in the metal plate 860 will be referred to as a second notch portion NC2, but the first notch portion NC1 and the second notch portion NC2 are exemplary and are not limited thereto.

For example, referring to FIG. 9, the first notch portion NC1 is a portion from which the adhesive layer 820, the polarizing plate 830, the display panel 840, and the back plate 850 are removed, and may be a space between an end portion of the cover window 110 and the side surface of the adhesive layer 820, the side surface of the polarizing plate 830, the side surface of the display panel 840, and the side surface of the back plate 850. The first notch portion NC1 may be disposed along the adhesive layer 820, the polarizing plate 830, the display panel 840, and the back plate 850. In addition, the second notch portion NC2 is a portion from which the metal plate 860 is removed, and may be a space between the end portion of the cover window 110 and the side surface of the metal plate 860.

The first notch portion NC1 is formed in the adhesive layer 820, the polarizing plate 830, the display panel 840, and the back plate 850 at a time, and the metal plate 860 having the second notch portion NC2 may be attached. In this case, a size of the second notch portion NC2 may be greater than that of the first notch portion NC1.

However, in FIG. 9, although the first notch portion NC1 and the second notch portion NC2 are illustrated to have different sizes, the first notch portion NC1 and the second notch portion NC2 may have the same size by forming the notch portion NC in the adhesive layer 820, the polarizing plate 830, the display panel 840, the back plate 850, and the metal plate 860 at a time, but the present disclosure is not limited thereto.

The conductive light blocking member 870 may cover the side surface of the adhesive layer 820, the side surface of the polarizing plate 830, the side surface of the display panel 840, and the side surface of the back plate 850 that are exposed through the first notch portion NC1, and the side surface of the metal plate 860 that is exposed through the second notch portion NC2. Specifically, the conductive light blocking member 870 may cover a boundary portion between the side surface of the adhesive layer 820 and the rear surface of the cover window 110, the side surface of the adhesive layer 820, the side surface of the polarizing plate 830, the side surface of the display panel 840, and the side surface of the back plate 850 in the first notch portion NC1. In addition, the conductive light blocking member 870 may cover a boundary portion between a rear surface of the back plate 850 and the side surface of the metal plate 860 and the side surface of the metal plate 860 in the second notch portion NC2. In addition, the conductive light blocking member 870 may overlap a portion of the print pattern BP.

Meanwhile, the conductive light blocking member 870 is disposed only on the side surface of the metal plate 860 in the second notch portion NC2 and is not disposed up to a rear surface of the metal plate 860. An end portion of the conductive light blocking member 870 may not be disposed on the rear surface of the metal plate 860. If the conductive light blocking member 870 is disposed up to the rear surface of the metal plate 860, a circuit board for driving an optical component and the conductive light blocking member 870 may interfere with each other, so that a short circuit defect may occur and interference with components such as a frame and the like may occur. Accordingly, the conductive light blocking member 870 may be formed only to the side surface of the metal plate 860 in the second notch portion NC2.

In the display device 800 according to another aspect of the present disclosure, the conductive light blocking member 870 is formed in the notch portion NC corresponding to a camera area CA, so that light leakage can be prevented and at the same time, static electricity of the cover window 110 can be discharged. Specifically, the notch portion NC is formed by cutting a portion of the adhesive layer 820, the polarizing plate 830, the display panel 840, the back plate 850, and the metal plate 860 under the cover window 110, so that the camera area CA in which a camera is disposed may be formed. In this case, in order to block the light emitted from the plurality of sub-pixels SP of the display panel 840 from being directed to the notch portion NC, the conductive light blocking member 870 covering the side surfaces of the adhesive layer 820, the polarizing plate 830, the display panel 840, the back plate 850, and the metal plate 860 in the notch portion NC may be formed. In this case, the conductive light blocking member 870 may be formed of a conductive material, so that static electricity generated in the cover window 110 may be discharged toward the metal plate 860 through the conductive light blocking member 870. Accordingly, in the display device 800 according to another exemplary aspect of the present disclosure, the conductive light blocking member 870 is formed in the notch portion NC, so that it is possible to block light inside the display panel 840 from being introduced to the camera area CA and at the same time, to discharge static electricity generated in the cover window 110, thereby allowing for improvements in reliability of the display device 800.

The exemplary aspects of the present disclosure can also be described as follows.

A display device according to an aspect of the present disclosure includes a display panel including a display area in which a plurality of sub-pixels are disposed and a camera area which is adjacent to the display area and in which a first hole is disposed, a first plate disposed on a rear surface of the display panel and including a second hole overlapping the first hole, a front member disposed on an upper surface of the display panel, and a light blocking member covering a rear surface of the front member which is exposed through the first hole, an inner surface of the first hole, and an inner surface of the second hole.

According to some aspects of the present disclosure, an end portion of the light blocking member may be disposed on a side surface of the first plate exposed through the second hole.

According to some aspects of the present disclosure, the display device may further include an adhesive layer disposed between the display panel and the front member, a polarizing plate disposed between the adhesive layer and the display panel, and a second plate disposed between the display panel and the first plate. The first hole may be disposed along the adhesive layer, the polarizing plate, the display panel, and the second plate.

According to some aspects of the present disclosure, a diameter of the first hole may be smaller than a diameter of the second hole. The light blocking member may cover a side surface of the adhesive layer, a side surface of the polarizing plate, a side surface of the display panel, and a side surface of the second plate which are exposed through the first hole, and a rear surface of the second plate and a side surface of the first plate which are exposed through the second hole.

According to some aspects of the present disclosure, a diameter of the first hole and a diameter of the second hole may be identical to each other. The light blocking member may cover a side surface of the adhesive layer, a side surface of the polarizing plate, a side surface of the display panel, and a side surface of the second plate which are exposed through the first hole, and a side surface of the first plate which is exposed through the second hole.

According to some aspects of the present disclosure, the camera area may be disposed between the plurality of sub-pixels of the display area. Light which travels toward the first hole among light emitted from the plurality of sub-pixels may be blocked by the light blocking member.

According to some aspects of the present disclosure, static electricity of the front member may be discharged to the first plate through the light blocking member.

According to some aspects of the present disclosure, the front member may include a pattern which is disposed to correspond to a circumference of the first hole in the rear surface of the front member. The light blocking member disposed on the rear surface of the front member may overlap the pattern.

According to some aspects of the present disclosure, at least one of the first hole and the second hole may overlap the pattern.

According to some aspects of the present disclosure, the light blocking member may be formed of a conductive member.

According to some aspects of the present disclosure, the light blocking member may be formed of a conductive ink or a conductive paste.

According to some aspects of the present disclosure, the light blocking member may overlap a portion of the first plate.

A display device according to another aspect of the present disclosure includes a display panel including a display area in which a plurality of sub-pixels are disposed and a camera area which is adjacent to the display area and which includes a first notch portion, a first plate disposed on a rear surface of the display panel and including a second notch portion overlapping the first notch portion, a front member disposed on an upper surface of the display panel, and a light blocking member covering a rear surface of the front member and a side surface of the display panel which are exposed through the first notch portion and a side surface of the first plate which is exposed through the second notch portion.

According to some aspects of the present disclosure, an end portion of the light blocking member may be disposed on the side surface of the first plate which is exposed through the second notch portion.

According to some aspects of the present disclosure, the display device may further include an adhesive layer disposed between the display panel and the front member, a polarizing plate disposed between the adhesive layer and the display panel, and a second plate disposed between the display panel and the first plate. The first notch portion may be disposed along the adhesive layer, the polarizing plate, the display panel, and the second plate.

According to some aspects of the present disclosure, the light blocking member may cover a side surface of the adhesive layer, a side surface of the polarizing plate, a side surface of the display panel, and a side surface of the second plate which are exposed through the first notch portion.

According to some aspects of the present disclosure, light which is directed toward the first notch portion among light emitted from the plurality of sub-pixels may be blocked by the light blocking member.

According to some aspects of the present disclosure, the first plate may be electrically grounded and configured to discharge static electricity of the front member through the light blocking member.

According to some aspects of the present disclosure, the light blocking member may be one of a conductive ink and a conductive paste.

According to some aspects of the present disclosure, the light blocking member may be formed of a conductive member.

According to some aspects of the present disclosure, the light blocking member may overlap a portion of the first plate.

It will be apparent to those skilled in the art that various modifications and variations can be made in the present disclosure without departing from the technical idea or scope of the disclosure. Thus, it is intended that the present disclosure covers the modifications and variations of this disclosure provided they come within the scope of the appended claims and their equivalents.

What is claimed is:

1. A display device, comprising:
a display panel including a display area in which a plurality of sub-pixels are disposed and a camera area which is adjacent to the display area and in which a first hole is disposed;
a first plate disposed on a rear surface of the display panel and including a second hole overlapping with the first hole;
a front member disposed on an upper surface of the display panel; and
a light blocking member covering a rear surface of the front member which is exposed through the first hole, an inner surface of the first hole, and an inner surface of the second hole.

2. The display device of claim 1, wherein the light blocking member has an end portion which is disposed on a side surface of the first plate exposed through the second hole.

3. The display device of claim 1, further comprising:
an adhesive layer disposed between the display panel and the front member;
a polarizing plate disposed between the adhesive layer and the display panel; and
a second plate between the display panel and the first plate,
wherein the first hole is disposed along the adhesive layer, the polarizing plate, the display panel, and the second plate.

4. The display device of claim 3, wherein the first hole has a diameter smaller than a diameter of the second hole, and
wherein the light blocking member covers a side surface of the adhesive layer, a side surface of the polarizing plate, a side surface of the display panel and a side surface of the second plate which are exposed through the first hole, and
wherein the light blocking member covers a rear surface of the second plate and a side surface of the first plate which are exposed through the second hole.

5. The display device of claim 3, wherein the first hole and the second hole have a diameter identical to each other, and
wherein the light blocking member covers a side surface of the adhesive layer a side surface of the polarizing plate, a side surface of the display panel, and a side surface of the second plate which are exposed through the first hole, and
wherein the light blocking member covers a side surface of the first plate which is exposed through the second hole.

6. The display device of claim 1, wherein the camera area is disposed between the plurality of sub-pixels of the display area, and
wherein light which travels toward the first hole among light emitted from the plurality of sub-pixels is blocked by the light blocking member.

7. The display device of claim 1, wherein static electricity of the front member is discharged to the first plate through the light blocking member.

8. The display device of claim 1, wherein the front member includes a pattern which is disposed to correspond to a circumference of the first hole in the rear surface of the front member, and
wherein the light blocking member disposed on the rear surface of the front member overlaps the pattern.

9. The display device of claim 8, wherein at least one of the first hole and the second hole overlaps the pattern.

10. The display device of claim 1, wherein the light blocking member includes a conductive member.

11. The display device of claim 1, wherein the light blocking member is formed of a conductive ink or a conductive paste.

12. The display device of claim 1, wherein the light blocking member overlaps with a portion of the first plate.

13. A display device, comprising:
a display panel including a display area having a plurality of sub-pixels and a camera area having a first notch portion and adjacent to the display area;
a first plate disposed on a rear surface of the display panel and having a second notch portion overlapping with the first notch portion;
a front member disposed on an upper surface of the display panel; and
a light blocking member covering a rear surface of the front member and a lateral surface of the display panel which are exposed through the first notch portion,
wherein a lateral surface of the first plate is exposed through the second notch portion.

14. The display device of claim 13, wherein the light blocking member has an end portion disposed on the lateral surface of the first plate which is exposed through the second notch portion.

15. The display device of claim 13, further comprising:
an adhesive layer disposed between the display panel and the front member;
a polarizing plate disposed between the adhesive layer and the display panel; and
a second plate between the display panel and the first plate,
wherein the first notch portion is disposed along the adhesive layer, the polarizing plate, the display panel, and the second plate.

16. The display device of claim 15, wherein the light blocking member covers a lateral surface of the adhesive layer, a lateral surface of the polarizing plate, a lateral surface of the display panel, and a lateral surface of the second plate which are exposed through the first notch portion.

17. The display device of claim 13, wherein the light blocking member blocks light directed toward the first notch portion among light emitted from the plurality of sub-pixels.

18. The display device of claim 13, wherein the first plate is electrically grounded and configured to discharge static electricity of the front member through the light blocking member.

19. The display device of claim 13, wherein the light blocking member is formed of one of a conductive ink and a conductive paste.

20. The display device of claim 13, wherein the light blocking member includes a conductive member.

21. The display device of claim 13, wherein the light blocking member overlaps with a portion of the first plate.
